(19) United States
(12) Patent Application Publication
(10) Pub. No.: US 2021/0381125 A1
(43) Pub. Date: Dec. 9, 2021

(54) EPITAXIAL DIRECTED ALD CRYSTAL GROWTH

(71) Applicant: Seagate Technology LLC, Fremont, CA (US)

(72) Inventors: Riyan A. Mendonsa, Edina, MN (US); Martin G. Blaber, Minneapolis, MN (US); Brett R. Herdendorf, Mound, MN (US); Kevin A. Gomez, Eden Prairie, MN (US)

(21) Appl. No.: 17/354,360

(22) Filed: Jun. 22, 2021

Related U.S. Application Data
(63) Continuation-in-part of application No. 16/745,132, filed on Jan. 16, 2020.
(60) Provisional application No. 63/059,435, filed on Jul. 31, 2020.
(60) Provisional application No. 62/815,858, filed on Mar. 8, 2019.

(51) Int. Cl. C30B 25/10; C30B 25/16; C23C 16/455

(52) U.S. Cl. CPC C30B 25/105; C30B 25/12; C23C 16/45527; C30B 25/16

(57) ABSTRACT

A method for making a monocrystalline structure is disclosed. The method includes depositing a first volume of a material on a substrate to create a first crystal seed and depositing a second volume of the material towards the substrate to nucleate with the first crystal seed to create a first initial epitaxial structure.

### RELATED APPLICATIONS

This application claims priority to U.S. Provisional Application No. 63/059,435, filed Jul. 31, 2020, and is a continuation-in-part of U.S. patent application Ser. No. 16/745,132, filed Jan. 16, 2020, which claims priority to U.S. Provisional Application No. 62/815,858, filed Mar. 8, 2019; all of the above-referenced applications being commonly assigned and incorporated by reference herein for all purposes.

### SUMMARY

In certain embodiments, a method for making a monocrystalline structure is disclosed. The method includes depositing a first volume of a material on a substrate to create a first crystal seed and depositing a second volume of the material towards the substrate to nucleate with the first crystal seed to create a first initial epitaxial structure.

In certain embodiments, method for making an active device with a crystalline structure is disclosed. The method includes depositing, one at a time, separate volumes of a material such that each volume of the material nucleates with the previously deposited material until the transistor structure is formed. The method further includes heating each separate volume of the material to encourage nucleation to the previously deposited material.

In certain embodiments, a system includes a chamber, a support structure disposed in the chamber and configured to support and position a substrate, and one or more heads. The one or more heads include an opening and an energy source, which is coupled to a near-field transducer for providing localized energy towards the support structure at select locations within the chamber. The system further includes circuitry configured to control deposition of separate volumes of a material, one at a time, through the opening such that each volume of the material nucleates with the previously deposited material. The circuitry is further configured to control an amount of energy from the energy source such that each separate volume of the material is heated to encourage nucleation to the previously deposited material.

While multiple embodiments are disclosed, still other embodiments of the present invention will become apparent to those skilled in the art from the following detailed description, which shows and describes illustrative embodiments of the invention. Accordingly, the drawings and detailed description are to be regarded as illustrative in nature and not restrictive.

### BRIEF DESCRIPTION OF THE DRAWINGS

FIG. 1 shows an ALD system, in accordance with certain embodiments of the present disclosure.

FIG. 2 shows a perspective view of a head, in accordance with certain embodiments of the present disclosure.

FIG. 3 shows a bottom view of the head of FIG. 2, in accordance with certain embodiments of the present disclosure.

FIG. 4 shows an energy source, waveguide, and near-field transducer, in accordance with certain embodiments of the present disclosure.

FIG. 5 shows a perspective view of a head, in accordance with certain embodiments of the present disclosure.

FIG. 6 shows a partial view of an ALD system, in accordance with certain embodiments of the present disclosure.

FIG. 7 shows heads and baffles for use in an ALD system, in accordance with certain embodiments of the present disclosure.

FIG. 8 shows a block diagram of steps of an ALD method, in accordance with certain embodiments of the present disclosure.

FIG. 9 shows a side view of an unfinished crystalline structure, in accordance with certain embodiments of the present disclosure.

FIG. 10 shows block diagram of steps of a deposition method, in accordance with certain embodiments of the present disclosure.

FIG. 11 shows a top view of a substrate and different crystalline structures, in accordance with certain embodiments of the present disclosure.

FIG. 12 shows a perspective view of a field-effect transistor, in accordance with certain embodiments of the present disclosure. FIG. 12 shows a perspective view of a field-effect transistor, in accordance with certain embodiments of the present disclosure.

FIG. 13 shows a block diagram of a crystalline structure, in accordance with certain embodiments of the present disclosure.

While the disclosure is amenable to various modifications and alternative forms, specific embodiments have been shown by way of example in the drawings and are described in detail below. The intention, however, is not to limit the disclosure to the particular embodiments described but instead is intended to cover all modifications, equivalents, and alternatives falling within the scope of the appended claims.

### DETAILED DESCRIPTION

Atomic layer deposition (ALD) is used for depositing atomically-thick layers onto a surface of a substrate. Current approaches for ALD involve sequentially moving various gaseous precursors (sometimes referred to as reactants) in and out of a reactor, the process of which is costly and takes significant time to deposit materials. For example, current approaches require the entire surface to be deposited upon before one precursor is purged from the reactor and another injected into the reactor. ALD is considered to be self-limiting such that deposition is automatically halted (e.g., no longer accumulates on the target surface) when all reactive sites on the target surface are occupied. As a result, each ALD layer is deposited nearly without defects such as point (i.e., zero-dimension), line (i.e., one-dimension), surface (i.e., two-dimension), or volume (i.e., three-dimension) defects. ALD is used most commonly in the semiconductor industry.

In a typical ALD process, two different precursors are repeatedly delivered and purged, in an alternating way, to and from a reaction chamber. As such, the precursors are not simultaneously present in the reactor chamber but instead are inserted in a series of sequential, non-overlapping pulses. The precursors react sequentially with the surface of a material such that a thin film is slowly deposited with repeated exposure to separate precursors. The precursors react with the substrate (or with an underlying deposited material) via half-reactions. During each ALD cycle, a first precursor is delivered into the reaction chamber (e.g., under vacuum) to allow the first precursor to react with a target surface (e.g., the substrate) such that a monolayer of the first precursor is formed. Excess (e.g., non-adsorbed) precursor is removed (e.g., via purging with an inert gas) from the reaction chamber. Then a second precursor is delivered into the reaction chamber to allow the second precursor to react with the monolayer of the first precursor coated onto the target surface. Excess precursor and by-products are next removed from the reaction chamber. This ALD cycle is repeated until the desired film thickness is achieved.

It is desirable to ensure sufficient reaction time to help achieve full adsorption density such that no reactive sites of the substrate are left empty. One approach to help increase adsorption density is to increase the rate of adsorption, such as by increasing the concentration and/or the sticking probability. As an example, increasing the temperature at the reaction site may increase sticking probability for many ALD reactions. Examples of ALD reactions include catalytic ALD of metal oxides (e.g., as high k-dielectric or insulating layers), thermal ALD of metals (e.g., as conductive pathways), ALD of polymers (e.g., for polymer surface functionalization), and ALD of particles (e.g., for protective coatings).

Certain embodiments of the present disclosure involve ALD systems, devices, and methods for providing activation energy to encourage reactions between the precursors. In particular, certain ALD systems, devices, and methods involve techniques for providing directed, localized energy transfer to encourage reactions to occur. Further, certain ALD systems, devices, and methods involve techniques for directed, localized delivery precursors within the chamber.

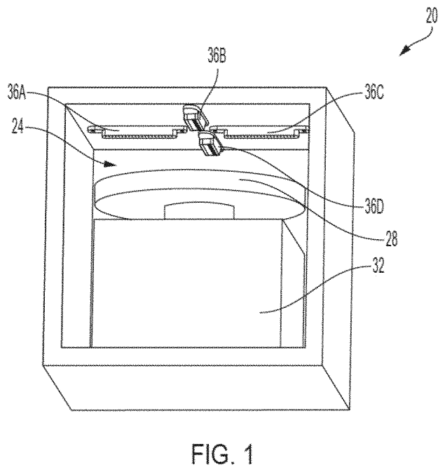

FIG. 1 shows a simplified depiction of an ALD system 20. The ALD system 20 includes a chamber 24 (e.g., vacuum chamber), a support structure 28 (e.g., a rotating bed, chuck, or table), an actuation assembly 32, and a plurality of devices 36A, 36B, 36C, and 36D, which are hereinafter referred to as heads (e.g., print heads or nozzles). In certain embodiments, the support structure 28 is configured to support a deposition target (e.g., a substrate or a work piece) and to rotate and/or to translate (e.g., linearly) to position the deposition target in an X-Y plane within the chamber. In various embodiments, the actuation assembly 32 is configured to position the support structure 28 (and therefore the deposition target supported by the support structure 28) along a Z-axis within the chamber 24. For example, the actuation assembly 32 can be configured to adjust, via one or more motors (e.g., servo motors), the working distance between the heads 36A-D and the deposition target, such as via positioning the support structure 28 towards or away from the heads 36A-D. In certain embodiments, the actuation assembly 32 rotates the support structure 28 via one or more motors. In other embodiments, the support structure 28 is coupled to a dedicated actuation system.

In some embodiments, the actuation assembly 32 is configured to adjust and/or maintain a predetermined working distance between the heads 36A-D and the deposition target. The predetermined working distance may change for different steps throughout the ALD process (e.g., method 1000 described below) depending on the size of features to be created by the ALD process. In certain embodiments, the actuation assembly 32 ensures that the same predetermined working distance is used to deposit both the first precursor and the second precursor. Ensuring the same predetermined working distance may involve lowering the support structure 28 after deposition of the first precursor to compensate for the layer thickness added by the deposited first precursor. As an example, a predetermined working distance for a 50 nm feature may be about 50 nm. If the first precursor creates a 1-nm-thick layer, the actuation assembly 32 can lower the support structure 28 by 1 nm such that the working distance is 50 nm during deposition of the second precursor. In certain embodiments, the support structure may be moved in the X-direction, Y-direction, and/or Z-direction via activating a servo system which may include one or more motors. In some embodiments, the heads 36A-D themselves are positionable within the chamber 24 and can rotate and/or adjust their relative positions with respect to the deposition target. In various embodiments, the ALD system 20 includes one or more position sensors for determining the X-position, the Y-position, and/or the Z-position. The one or more position sensors may be friction-based, capacitance-based, optical-based, and/or magnet-based.

As illustrated, the heads 36A-D may be disposed substantially radially within the chamber 24. In various embodiments, the heads 36A-D are configured to direct one or more precursors (e.g., gaseous precursors) into the chamber 24 towards a target region (e.g., the deposition target or portions thereof). In some embodiments, heads 36A and 36C are configured to direct a first precursor and heads 36B and 36D are configured to direct a second precursor. Having heads dedicated to injecting one type of precursor (rather than multiple precursors) can help reduce build-up of precursor material on the heads.

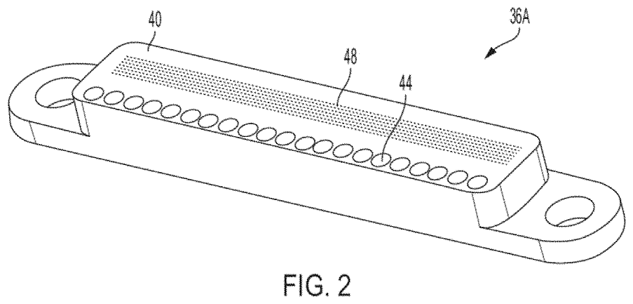

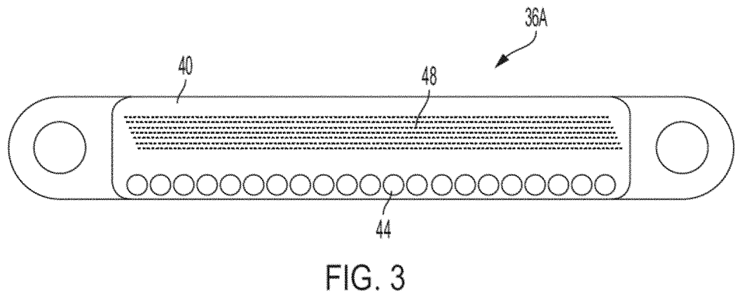

FIGS. 2-3 show a head 36A in a perspective view and a bottom view, respectively. While the head illustrated in FIGS. 2-3 is labeled as the head 36A, it is to be understood that the heads 36A-D may be substantially similar or identical, and thus, the descriptions of the head 36A may be applicable to the other heads 36B-D.

As illustrated, the head 36A includes a body 40 having one or more openings 44 (e.g., gas inlets) and one or more energy sources 48. In various embodiments, the one or more openings 44 are configured to deliver and/or to guide a precursor towards a target region such as the deposition target or parts thereof within the chamber 24. The one or more openings 44 may be arranged substantially linearly and/or side-by-side, such as along a length of the head 36A. In certain embodiments, the one or more energy sources 48 includes one or more lasers (e.g., VCSELs and the like) configured to deliver heat towards the target region to heat the surface of the substrate to encourage reaction of the precursor delivered via the one or more openings 44.

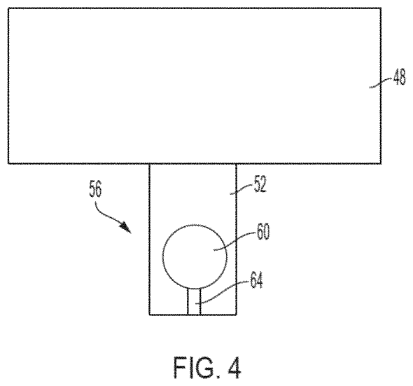

In certain embodiments, as shown in FIG. 4, the energy sources 48 are optically coupled to one or more NFTs 56 (e.g., plasmonic NFTs) via a waveguide 52. The NFTs 56 may include a metal disk 60 and a peg 64 below the disk 60. In embodiments, the distal end of the peg 64 is arranged to face the target surface. When light emitted by the energy sources 48 hits the disk 60, the light is converted to an electric surface current. This surface current and the associated electromagnetic fields are known as surface plasmons, which propagate along the surface of the disk 60 into the peg 64, which emits heat at a precise and limited point or target. As such, the NFTs 56 are configured to create a hotspot on a target region of a target surface such that temperature rises at the target region. The heated target region can encourage reaction of the precursor at that particular region. The energy sources 48 and/or NFTs 56 can be individually addressable/activated to create layers in particular patterns. As such, the energy sources 48 and/or NFTs 56 can be used to create features that otherwise would require additional processing steps such as masking, etc.

In certain embodiments, the head 36A does not include an NFT 56 and instead solely uses a laser for providing energy. Such embodiments, may be used for creating lower resolution features. In other embodiments, the ALD system 20 includes some heads 36A-D with one or more NFTs 56 and some devices without NFTs 56. Further, although the heads 36A-D are shown as being used to inject the precursors and provide energy to encourage reaction of the precursors, the injection functionality and the energy functionality can be provided by separate components in the ALD system 20. For example, the heads 36A-D could include the energy sources 48, the waveguides 52, and the NFTs 56 while another component could include openings to inject the precursors into the chamber 24.

According to some embodiments, the NFT 56 may be comprised of a metal that achieves surface plasmonic resonance in response to an applied energy (e.g., light from a laser). In some embodiments, the NFT 56 comprises one or more of aluminum (Al), antimony (Sb), bismuth (Bi), chromium (Cr), cobalt (Co), copper (Cu), erbium (Er), gadolinium (Gd), gallium (Ga), gold (Au), hafnium (Hf), indium (In), iridium (Ir), iron (Fe), manganese (Mn), molybdenum (Mo), nickel (Ni), niobium (Nb), osmium (Os), palladium (Pd), platinum (Pt), rhenium (Re), rhodium (Rh), ruthenium (Ru), scandium (Sc), silicon (Si), silver (Ag), tantalum (Ta), tin (Sn), titanium (Ti), vanadium (V), tungsten (W), ytterbium (Yb), yttrium (Y), zirconium (Zr), or combinations thereof. In certain embodiments, the NFT 56 includes a binary alloy, a ternary, a lanthanide, an actinide, a dispersion, an intermetallic such as a ternary silicide, a nitride, or a carbide, an oxide such as a conducting oxide, and/or a metal doped with oxide, carbide or nitride nanoparticles. Illustrative oxide nanoparticles can include, for example, oxides of yttrium (Y), lanthanum (La), barium (Ba), strontium (Sr), erbium (Er), zirconium (Zr), hafnium (Hf), germanium (Ge), silicon (Si), calcium (Ca), aluminum (Al), magnesium (Mg), titanium (Ti), cerium (Ce), tantalum (Ta), tungsten (W), thorium (Th), or combinations thereof. Illustrative nitride nanoparticles can include, for example, nitrides of zirconium (Zr), titanium (Ti), tantalum (Ta), aluminum (Al), boron (B), niobium (Nb), silicon (Si), indium (In), iron (Fe), copper (Cu), tungsten (W), or combinations thereof. Illustrative carbide nanoparticles can include, for example carbides of silicon (Si), aluminum (Al), boron (B), zirconium (Zr), tungsten (W), titanium (Ti), niobium (Nb), or combinations thereof.

In various embodiments, the NFT 56 comprises materials and/or is shaped to emit wavelengths (e.g., ultraviolet wavelengths) that are better suited for certain precursors. For example, an NFT comprising aluminum (Al), gallium (Ga), rhodium (Rh), indium (In), or iridium (Ir) may operate better in the ultraviolet spectrum for precursors comprising alumina or titania. As another example, an NFT comprising gold (Au) may operate better in the visible and infrared spectrum with precursors comprising ruthenium (Ru), tantalum (Ta), silicon (Si), titanium (Ti), germanium (Ge), platinum (Pt) or nitrides such as TiN and TaN.

In some embodiments, as the substrate is rotated, a first precursor is injected into the chamber 24 via the one or more openings 44 in head 36A. The deposition target (e.g., substrate) is heated by the energy source 48 and/or NFT 56. For example, when the energy source 48 is a laser, the laser is activated to emit light towards the waveguide 52, which directs the emitted light to the NFT 56. The NFT 56 converts the emitted light to localized, focused energy (e.g., heat) that is directed to at least select locations (e.g., regions or portions) of the deposition target. For example, the energy could be directed towards the deposition target in a predetermined pattern to cause the first precursor to react and form a monolayer of a first material in a given pattern. In certain embodiments, the deposition target is activated (e.g., thermally activated, photonically activated) by just a laser and optionally an optically coupled waveguide to cause the first precursor to react.

In certain embodiments, once the first precursor has reacted and formed a monolayer of a first material, the chamber 24 is next purged (e.g., with an inert gas). Next, as the deposition target rotates, a second precursor is passed through openings 44 of another head 36B. The deposition target (e.g., substrate) is activated by the energy source 48 and/or NFT 56 of the head 36B. In some embodiments, the un-reacted precursors and reaction by-products can be continuously or intermittently removed, such as by purging and/or applying vacuum, from the chamber 24 to remove undesired material from the chamber 24. In certain embodiments, an inert gas (e.g., argon) is injected into the chamber 24 to help purge undesired material from the chamber 24.

In certain embodiments (e.g., embodiments involving thermal activation), the ALD system 20 can include a preheater (e.g., a heating unit) configured to supply heat to the deposition target, such as via the support structure 28 to reduce the amount of energy required from the energy sources 48 and/or the NFTs 56. In some embodiments, the ALD system 20 includes an energy monitor configured to monitor the amount of energy delivered to the deposition target from the energy source 48, the measured amount of energy may be used to guide adjustment of one or more parameters of the energy source 48.

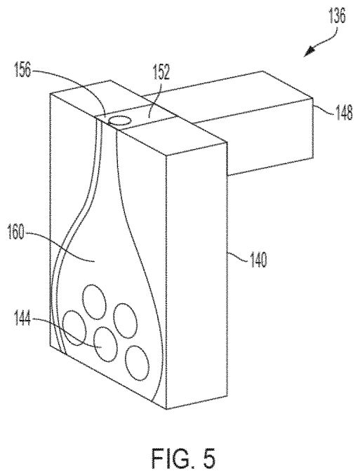

FIG. 5 shows an alternative head design, which could be used in the ALD system 20 shown in FIG. 1. The head 136 may be used for ALD systems that feature a support structure that moves in the X-Y direction rather than rotating. In other embodiments, the head 136 itself can move in the X-Y direction rather than, or in addition to, the support structure. The head 136 includes a body 140, an opening 144, an energy source 148 (e.g., laser), a waveguide 152, a NFT 156, and an injection channel 160. As illustrated, the opening 144 is fluidically connected to the injection channel 160. The injection channel 160 can act as an air bearing, and the fly height (e.g., distance to the deposition target) can be controlled via heat, pressure, and/or force of the precursor injected into the chamber. The energy source 148, the waveguide 152, and the NFT 156 may be optically coupled together. In various embodiments, the energy source 148 is configured to emit light into the waveguide 152, the waveguide 152 is configured to direct the light to the NFT 156, and the NFT 156 is configured to convert the light to energy that is directed towards a surface of the substrate. The energy can help activate reaction of a precursor. The NFT 156 can comprise one or more of the materials listed above with respect to the NFT 56 of FIG. 4.

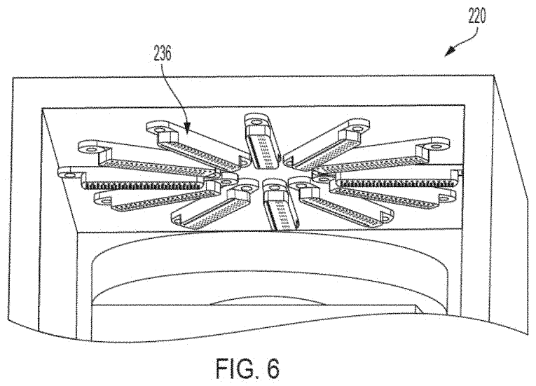

FIG. 6 shows an ALD system 220 similar to the ALD system 20 shown in FIG. 1. As shown in FIG. 6, ALD systems can include any number of individual heads to deliver the precursors and/or the energy for encouraging reaction of the precursors. As illustrated, ALD system 220 includes twelve heads 236. In certain embodiments, some of the heads 236 are used for delivering a first precursor and some of the heads 236 are used for delivering a second precursor. In certain embodiments, some of the heads 236 are used to deliver a third precursor.

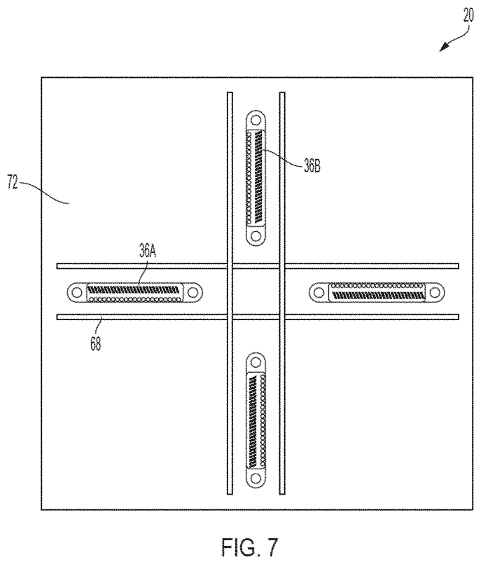

FIG. 7 shows features that can be incorporated into an ALD system (e.g., the ALD systems 20, 220) to help direct injection of precursors within a chamber. FIG. 7 shows baffles 68, which may also be referred to as dividers, separators, and the like. The baffles 68 may separate at least one of the heads 36A-D from at least one of the other heads 36A-D. The baffles 68 may be configured to define a plurality of sub-chambers each confining one or more of the heads 36A-D to confine precursors delivered by the heads 36A-D within their respective sub-chamber. In certain embodiments, each of the heads 36A-D may be positioned in between at least two of the baffles 68, which may be substantially parallel to each other. In some embodiments, the baffles 68 may be disposed on a top 72 of the chamber 24 and extend downward (e.g., towards the support structure). The use of baffles 68 may help accelerate the deposition process by requiring less gas (e.g., concentrating the precursor) to be delivered and less time for purging and/or vacuuming. The use of baffles 68 may further accelerate the deposition process by allowing multiple precursors to be in the chamber 24 simultaneously, such as having a first precursor in a first sub-chamber and a second precursor in a second sub-chamber simultaneously.

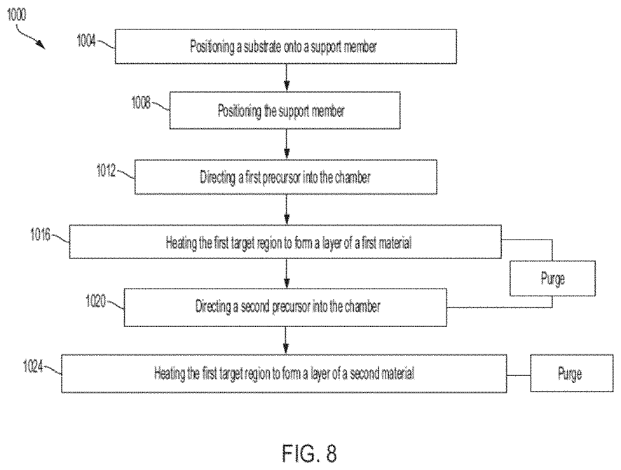

FIG. 8 depicts an illustrative method 300 for an ALD process. The method 300 includes positioning a substrate onto the support structure (block 302), positioning the support structure to be near the one or more heads such that a top surface of the substrate is at a predetermined working distance from the one or more heads (block 304), directing a first precursor into the chamber towards a first target region of the substrate via a first head of the one or more heads (block 306), activating the first target region to cause the first precursor to react and form a first material layer on the substrate (block 308), directing a second precursor into the chamber towards the first target region of the substrate via a second head of the one or more heads (block 310), and activating the first target region to cause the second precursor to react and form a second material layer on the first material layer (block 312). The first target region includes only select regions of the substrate (e.g., the deposition target).

In various embodiments, the process 302 of positioning a substrate (e.g., the deposition target) onto the support structure (e.g., support structure 28) includes securing the substrate onto the support structure. In certain embodiments, positioning the substrate includes exposing select regions of the substrate for material deposition. In some embodiments, the process 304 of positioning the support structure to be near the one or more heads such that a top surface of the substrate is at a predetermined working distance from the one or more heads (e.g., the heads 36A-D) includes translating and/or rotating the support structure to adjust the relative position between the select regions and the one or more heads 36A-D. For example, translating and/or rotating the support structure 28 includes activating a servo system, which may include activating a Z-axis actuation assembly. In some embodiments, positioning the support structure includes continuously or periodically (e.g., after each layer of material deposition) adjusting a working distance to maintain the predetermined working distance between the top surface of the substrate and the one or more heads 36A-D.

In certain embodiments, the process 306 of directing a first precursor into the chamber towards a first target region of the substrate via a first head (e.g., head 36A) of the one or more heads includes emitting the first precursor from one or more emission openings (e.g., one or more emission openings 44) of the first head. In some embodiments, the process 308 of activating the first target region to cause the first precursor to react and form a first material layer on the substrate includes activating an energy source (e.g., energy source 48) to deliver energy (e.g., by emitting light) into a waveguide (e.g., waveguide 52), directing the energy to an NFT (e.g., NFT 56) via the waveguide, and converting the energy from the energy source into an activation energy (e.g., heat) via the NFT.

In certain embodiments, the process 310 of directing a second precursor into the chamber towards the first target region of the substrate via a second head (e.g., head 36B) of the one or more heads includes emitting the first precursor from one or more emission openings of the second head. In some embodiments, the process 312 of activating the first target region to cause the second precursor to react and form a second material layer on the first material layer includes activating an energy source to deliver energy into a waveguide, directing the energy to an NFT via the waveguide, and converting the energy from the energy source into activation energy via the NFT. In various embodiments, the method 300 includes purging the chamber and/or adjusting the working distance, following the formation of the first material layer and/or after the formation of the second material layer such that excess precursors and reaction by-products are removed.

In certain embodiments, the method 300 includes repeating the process of 306, the process of 308, the process of 310, the process of 312, and optionally one or more purging processes. The repeating of the processes may continue until a target deposition thickness is reached.

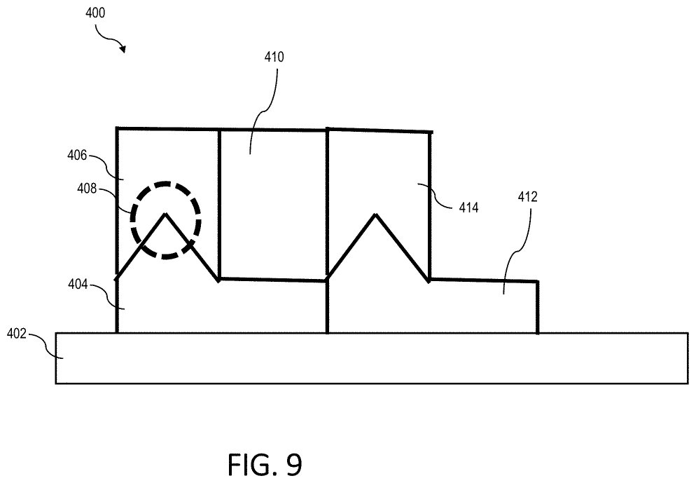

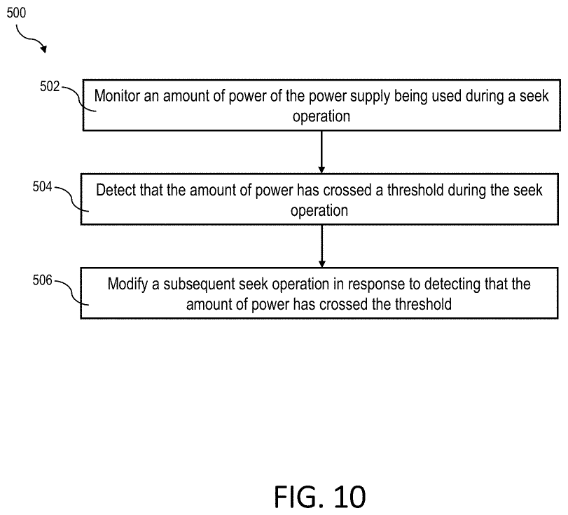

FIG. 9 shows a crystalline structure 400 that can be made by various deposition techniques that utilize heat and/or optical energy such as ALD. For example, the crystalline structure 400 can be made by the ALD system 20 described above. FIG. 10 outlines a method 500 that can be used to make the crystalline structure 400

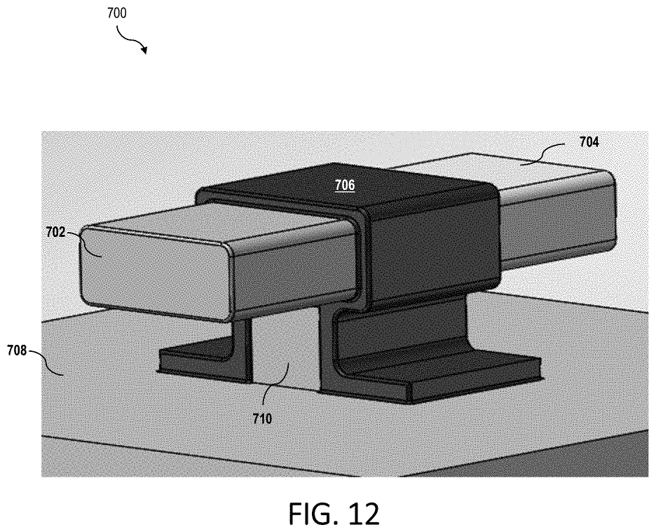

The crystalline structure 400 is positioned on a substrate 402. The crystalline structure 400 is shown in FIG. 9 as comprising only the first few individual volumes of material that are deposited on the substrate 402 and not the entire finished structure. (An example finished crystalline structure is shown in FIG. 12.) The crystalline structure 400 shown in FIG. 9 is made by depositing a first volume of material 404 on the substrate 402 (block 502 in FIG. 10). The first volume of material 404 can be considered to be a crystal seed because it is the initial part of the crystalline structure 400 on the substrate 402.

Next, a second volume of the material 406 is directed towards the substrate 402 and deposited (block 504 in FIG. 10). Because the first volume of the material 404 is the only material on the substrate 402, the second volume of the material 406 will nucleate with the first volume of the material 404. The nucleated structure can be considered to be an initial epitaxial structure because the first and second volumes of the material are grown epitaxially. In certain embodiments, the first volume of the material 404 is positioned between the substrate 402 and the second volume of the material 406.

In certain embodiment, the first volume of the material 404 and the second volume of the material 406 are heated to encourage nucleation of the first volume of the material 404 with the second volume of the material 406 (block 506 in FIG. 10). Heating can include directing a spot of energy 408 towards one or both of the first volume of the material 404 and the second volume of the material 406. For example, using the ALD system 20, the spot of energy 408 can be created and directed towards the substrate using one of the heads 36-D. The support structure 28 can position the substrate 402 such that the spot of energy 408 hits the desired target. The desired target can be on a top surface of the first volume of material 404 such that the second volume of material 406 nucleates and grows away from the substrate 402.

The crystalline structure 400 can continue to be epitaxially grown by depositing additional volumes of material such that each additional volume of the material nucleates to the previously deposited material. A spot of energy can be applied for each additional volume to encourage nucleation. The additional deposition of material can continue until a final desired structure is formed. The final desired structure can be a monocrystalline structure. As will be described in more detail below, examples of the final desired structure include transistors, photodetectors, and other active devices.

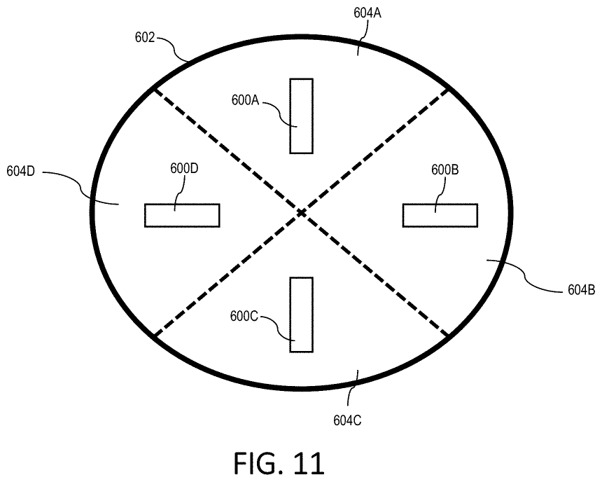

FIG. 11 shows a top view of different crystalline structures 600A-D positioned on a substrate 602. Each crystalline structure 600A-D is positioned in a different work volume 604A-D around the substrate 602. Further, each crystalline structure 600A-D can be created using deposition techniques described above. For example, each crystalline structure 600A-D can be created in the separate work volumes 604A-D by depositing a crystal seed and then additional separate volumes of a material such that each volume of the material nucleates with the previously deposited material until the crystalline structures 600A-D are complete. Further, each separate volume of the material can be heated to encourage nucleation to the previously deposited material. Using the ALD system 20, each crystalline structure 600A-D can be created by a separate head 36A-D or a combination of heads.

Although only four workspace volumes 604A-D are shown in FIG. 11, additional workspace volumes can be used. However, the crystalline structures in each workspace volume should be far enough apart so that volumes of material being deposited in separate workspace volumes will only nucleate to material within the desired workspace volume. Put another way, the crystalline structures should be spaced such that nucleation sites for respective deposited material is limited to the intended nucleation sites. For example, as the respective next volumes of material are being deposited, each workspace volume 604A-D can be void of all materials except for the substrate and the intended target crystalline structure.

The crystalline structures 600A-D can be different from each other but created simultaneously. For example, the crystalline structure 600A can be a transistor while the other crystalline structures 600B-D can be photodetectors. As another example, the crystalline structures 600A-D can all be transistors but can be made from different materials and/or with different dimensions. Further, each crystalline structure 600A-D can comprise different materials from the other crystalline structures. Although transistors and photodetectors are given as examples of active devices capable of being made by the methods described herein, the methods can be used to create other types of active devices.

FIG. 12 shows a field-effect transistor (FET) 700—part of which can be made using the deposition approaches described above. The FET 700 includes a source 702, a drain 704, and a gate 706 positioned on a substrate 708. The source 702 and the drain 704 can be created by first depositing a base 710 using the deposition approaches described above. For example, the base 710 can created by depositing, one at a time, separate volumes of a material such that each volume of the material nucleates with the previously deposited material until the base 710 is formed. Once the base 710 is formed, the source 702 and the drain 704 can be formed by depositing, one at a time, separate volumes of a material such that each volume of the material nucleates with the previously deposited material. When forming the source 702, drain 704, and base 710, each separate volume of the material can be heated to encourage nucleation to the previously deposited material. Together, the source 702, drain 704, and base 710 can be considered to be a monocrystalline structure that is three dimensional and that is epitaxially grown. Once the source 702, drain 704, and base 710 are formed, the gate 706 can be created from a different material and using different (but similar) deposition approaches such as traditional deposition techniques.

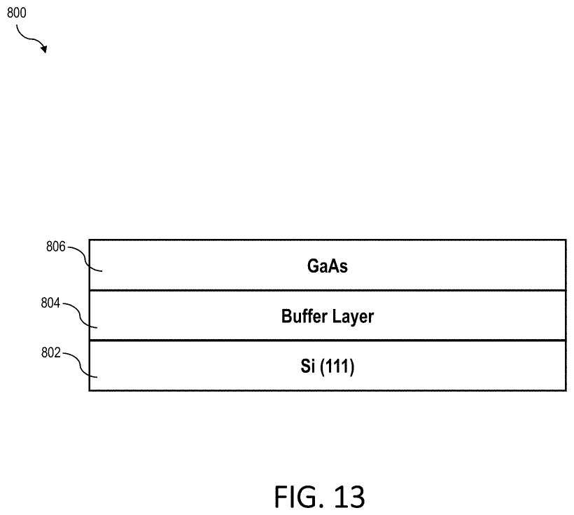

FIG. 13 shows a block diagram of a crystalline structure 800 that utilizes a buffer layer that converts or transforms a substrate's crystalline properties to be compatible with III-V and II-VI semiconductor materials. The crystalline structure 800 can be made using the deposition approaches described above.

The crystalline structure 800 includes a substrate 802, which in this example comprises silicon with a (111) orientation. In general, III-V and II-VI semiconductor materials cannot be epitaxially grown on (111) silicon because the orientations of the (111) silicon and the semiconductor materials are dissimilar. As such, a buffer layer 804 can be deposited on the substrate 802 using the deposition approaches described above. The buffer layer 804 can comprise a material that has a crystalline orientation that can be epitaxially grown on silicon (111) but that also allows III-V and II-VI semiconductor materials to grow epitaxially on the buffer layer 804.

After the buffer layer 804 is deposited, a semiconductor layer 806 comprising, for example, a III-V material such as GaAs can be deposited on the buffer layer 804. As such, with the use of the buffer layer 804, the semiconductor layer 806 comprising a material with a dissimilar crystalline orientation compared to silicon (111) can be epitaxially grown on silicon (111). Although only one buffer layer is shown, the crystalline structure 800 may include additional buffer layers depending on how dissimilar the silicon (111) substrate 802 is from the desired semiconductor material.

Various modifications and additions can be made to the embodiments disclosed without departing from the scope of this disclosure. For example, while the embodiments described above refer to particular features, the scope of this disclosure also includes embodiments having different combinations of features and embodiments that do not include all of the described features. Accordingly, the scope of the present disclosure is intended to include all such alternatives, modifications, and variations as falling within the scope of the claims, together with all equivalents thereof.

We claim:

1. A method for making a monocrystalline structure, the method comprising:
depositing a first volume of a material on a substrate to create a first crystal seed; and
depositing a second volume of the material towards the substrate to nucleate with the first crystal seed to create a first initial epitaxial structure.

2. The method of claim 1, further comprising:
heating the first volume of the material and the second volume of the material to encourage nucleation of the second volume of the material to the first volume of the material.

3. The method of claim 2, wherein the heating includes directing a spot of energy towards one or both of the first volume of the material and the second volume of the material.

4. The method of claim 3, wherein the spot of energy is created using a device that includes a near-field transducer and a laser.

5. The method of claim 4, wherein the device includes an opening through which the material passes before being deposited.

6. The method of claim 1, further comprising:
depositing, one at a time, additional volumes of the material such that each additional volume of the material adds to the first initial epitaxial structure to create a larger epitaxial structure.

7. The method of claim 6, further comprising:
heating each additional volume of the material to encourage nucleation to previously deposited volumes of the material to create the larger epitaxial structure.

8. The method of claim 6, wherein the larger epitaxial structure forms part of an active device.

9. The method of claim 6, wherein the first volume of the material is deposited in a first workspace volume, wherein the second volume of the material is deposited in the first workspace volume, the method further comprising:
depositing a third volume of a material on the substrate in a second workspace volume to create a second crystal seed;
depositing a fourth volume of the material towards the substrate in the second workspace volume to nucleate with the second crystal seed to create a second initial epitaxial structure; and
depositing, one at a time, additional volumes of the material in the second workspace volume such that each additional volume of the material adds to the second initial epitaxial structure to create a larger epitaxial structure.

10. The method of claim 9, wherein at least one of the depositing steps recited in claims 1 and 5 occur in parallel with at least one of the additional depositing steps recited in claim 8.

11. The method of claim 9, wherein each of the depositing steps is followed by a heating step.

12. The method of claim 11, wherein the heating of the first volume of the material and the second volume of the material is carried out by a first heating device with a first near-field transducer, wherein the heating of the third volume, the fourth volume, and the additional volumes of the material is carried out by a second heating device with a second near-field transducer.

13. The method of claim 1, wherein the additional volumes of the material are deposited until the monocrystalline structure is created.

14. The method of claim 1, wherein the first volume of the material is deposited in a first workspace volume, wherein the second volume of the material is deposited in the first workspace volume that only contains the substrate and the first volume of the material.

15. The method of claim 1, wherein the first volume of the material is positioned between the substrate and the second volume of the material.

16. The method of claim 15, wherein the first volume of the material and the second volume of the material are heated such that the second volume of material nucleates and grows away from the substrate.

17. A method for making an active device with a crystalline structure, the method comprising:
depositing, one at a time, separate volumes of a material such that each volume of the material nucleates with the previously deposited material until the transistor structure is formed; and
heating each separate volume of the material to encourage nucleation to the previously deposited material.

18. The method of claim 17, wherein the crystalline structure is monocrystalline.

19. The method of claim 17, wherein the active device includes a source and a drain.

20. A system comprising:
a chamber;
a support structure disposed in the chamber and configured to support and position a substrate;
one or more heads including an opening and an energy source, the energy source is coupled to a near-field transducer for providing localized energy towards the support structure at select locations within the chamber; and
circuitry configured to:
control deposition of separate volumes of a material, one at a time, through the opening such that each volume of the material nucleates with the previously deposited material, and
control an amount of energy from the energy source such that each separate volume of the material is heated to encourage nucleation to the previously deposited material.
